(19) United States
(12) Patent Application Publication
(10) Pub. No.: US 2007/0161190 A1
(43) Pub. Date: Jul. 12, 2007

(54) Split-gate-type nonvolatile memory device and method of fabricating the same

(75) Inventors: Sung-Kyoo Park, Seoul (KR); Hong-Kook Min, Yongin-si (KR); Chang-Mo Park, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/648,959

(22) Filed: Jan. 3, 2007

(30) Foreign Application Priority Data
Jan. 6, 2006 (KR) 10-2006-0001887

(51) Int. Cl. H01L 21/336

(52) U.S. Cl. 438/257

(57) ABSTRACT

Provided are a split-gate-type nonvolatile memory device and method of fabricating the same. The method includes forming isolation patterns defining active regions in a predetermined region of a semiconductor substrate. A first conductive layer is formed on the resultant structure having the isolation patterns. The first conductive layer has openings exposing both ends of the isolation patterns. Mask patterns are formed between the openings on the first conductive layer, thereby exposing a top surface of the first conductive layer as a rectangular type. The exposed top surface of the first conductive layer is thermally oxidized to form silicon oxide patterns with rectangular shapes. The first conductive layer is anisotropically etched using the silicon oxide patterns as etch masks to form floating conductive patterns. Thereafter, control gate electrodes are formed across the isolation patterns on the silicon oxide patterns.

This application relies for priority upon Korean Patent Application No. 10-2006-0001887, filed in the Korean Intellectual Property Office on Jan. 6, 2006, the contents of which are herein incorporated by reference in their entirety.

### BACKGROUND OF THE INVENTION

1. Field of the Invention

The present invention relates to a semiconductor device and method of fabricating the same, and more particularly, to a split-gate-type nonvolatile memory device and method of fabricating the same.

2. Description of the Related Art

FIG. 1 is a plan view illustrating a conventional method of fabricating a split-gate-type nonvolatile memory device.

Referring to FIG. 1, isolation patterns 20 are disposed in a predetermined region of a semiconductor substrate 10 to define active regions 30. The isolation patterns 20 are 2-dimensionally disposed in a first direction e₁ and in a second direction e₂ that is orthogonal to the first direction e₁. Each of the isolation patterns 20 takes on an island shape with a major axis parallel to the first direction e₁. A pair of control gate electrodes 40 are disposed over each of the isolation patterns 20 in a direction parallel to the second direction e₂.

Drain regions D are provided in the active region 30 between the pair of control gate electrodes 40, while source regions S parallel to the second direction e₂ are provided in the active region 30 outside the pair of control gate electrodes 40. The drain regions D are connected to bit lines (not shown) crossing over the control gate electrodes 40 through contact plugs 60.

Further, a gate insulating layer, a floating gate electrode 50, and an inter-gate dielectric pattern are sequentially stacked between the control gate electrode 40 and the active region 30. In this case, the floating gate electrodes 50 are separated from one another and spaced apart from the control gate electrodes 40. As a result, the floating gate electrodes 50 are 2-dimensionally arranged as island types and stand electrically isolated. The control gate electrode 40 extends from the top of the floating gate electrode 50 to the top of the semiconductor substrate 10 adjacent to the drain region D such that the control gate electrode 40 serves as a split gate electrode.

In the conventional art, the formation of the floating gate electrode 50 includes forming a polycrystalline silicon (poly-Si) layer on the entire surface of the resultant structure having the gate insulating layer and forming an island-shaped photoresist pattern to define the floating gate electrode 50. However, an increase in the integration density of semiconductor devices gives rise to a problem in that the photoresist pattern takes on a rounded shape instead of a designed rectangular shape. As a result, as shown in FIG. 1, the floating gate electrode 50, which is patterned using the photoresist pattern as an etch mask, also has rounded corners with a very great radius of curvature. This phenomenon causes a short channel effect to a nonvolatile memory transistor because the linewidth of the floating gate electrode 50 determines the channel length of a transistor.

### SUMMARY OF THE INVENTION

The present invention provides a split-gate-type nonvolatile memory device that prevents a floating conductive electrode from having rounded corners.

The present invention also provides a method of fabricating a split-gate-type nonvolatile memory device that prevents a floating conductive electrode from having rounded corners.

According to one aspect, the present invention is directed to a method of fabricating a split-gate-type nonvolatile memory device. The method includes forming isolation patterns defining active regions in a predetermined region of a semiconductor substrate. A first conductive layer is formed on the resultant structure having the isolation patterns. The first conductive layer has openings exposing both ends of the isolation patterns. Mask patterns are formed between the openings on the first conductive layer, thereby exposing a top surface of the first conductive layer as a rectangular type. The exposed top surface of the first conductive layer is thermally oxidized to form silicon oxide patterns with rectangular shapes. The first conductive layer is anisotropically etched using the silicon oxide patterns as etch masks to form floating conductive patterns. Control gate electrodes are formed across the isolation patterns on the silicon oxide patterns.

In one embodiment of the present invention, the forming of the first conductive layer having the openings may include forming the first conductive layer on the resultant structure having the isolation patterns; and patterning the first conductive layer to form the openings that are 2-dimensionally arranged on the semiconductor substrate and expose top surfaces of the isolation patterns. In this case, the openings may define two sidewalls parallel to major axes of the isolation patterns of the floating conductive patterns.

Before forming the silicon oxide patterns, spacer patterns may be further formed on inner walls of the openings. In this case, the mask patterns and the spacer patterns may be formed of an insulating layer having an etch selectivity with respect to the isolation patterns and the first conductive layer. For example, the mask patterns and the spacer patterns may be formed of a silicon nitride layer or a silicon oxide layer.

Also, the mask patterns may be formed parallel to the control gate electrodes. Thus, two sidewalls vertical to major axes of the isolation patterns of the floating conductive patterns may be defined by the mask patterns.

Furthermore, before forming the first conductive layer, a gate insulating layer may be further formed on top surfaces of the active regions. In this case, the forming of the floating conductive patterns may include anisotropically etching the first conductive layer using the silicon oxide patterns as etch masks until a top surface of the gate insulating layer is exposed; and anisotropically etching the gate insulating layer using the silicon oxide patterns as etch masks. Thus, the top surfaces of the active regions between the floating conductive patterns are exposed.

In one embodiment of the present invention, a tunnel insulating layer may be further formed on the exposed top surfaces of the active regions after anisotropically etching the gate insulating layer and before forming the control gate electrodes. Also, before forming the control gate electrodes, an inter-gate dielectric layer may be further formed on the resultant structure having the floating conductive patterns. In this case, the inter-gate dielectric layer may be formed of at least one of a silicon oxide layer and a silicon nitride layer.

According to the present invention, since the floating conductive patterns are formed using the rectangular silicon oxide patterns as etch masks, a difference between the length of the floating conductive pattern measured on the edge of the active region in a vertical direction to the control gate electrodes and the length of the floating conductive pattern measured on the center of the active region in the vertical direction to the control gate electrodes may be less than a tenth the smaller one of the two lengths.

According to another aspect, the present invention is directed to a split-gate-type nonvolatile memory device which includes isolation patterns disposed in a predetermined region of a semiconductor substrate to define active regions. Control gate electrodes are disposed across the isolation patterns. Floating conductive patterns are interposed between the control gate electrodes and the active regions. An inter-gate dielectric layer is interposed between the control gate electrodes and the floating conductive patterns. A gate insulating layer is interposed between the floating conductive patterns and the active regions. In this case, the floating conductive patterns have corners with a radius of curvature less than half the width of the active regions.

According to the present invention, the active regions may include first active regions disposed in a vertical direction to the control gate electrodes; and second active regions connecting the foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

on the center of the first active region may be less than a tenth the smaller one of the two lengths.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a plan view illustrating a conventional method of fabricating a split-gate-type nonvolatile memory device.

FIGS. 2A through 9A are plan views illustrating a method of fabricating a split-gate-type nonvolatile memory device according to an embodiment of the present invention.

FIGS. 2B through 9B are cross sectional views taken along dotted lines I-I′ of FIGS. 2A through 9A, respectively.

FIGS. 2C through 9C are cross sectional views taken along dotted lines II-II′ of FIGS. 2A through 9A, respectively; and

FIGS. 2D through 9D are cross sectional views taken along dotted lines III-III′ of FIGS. 2A through 9A, respectively.

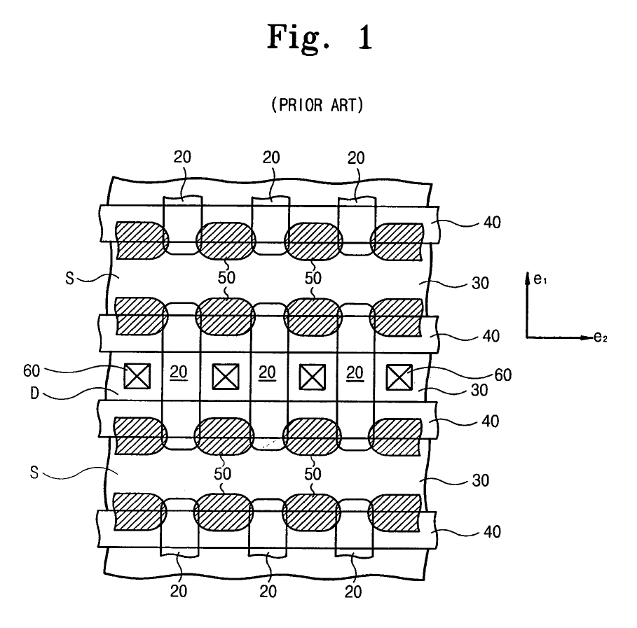

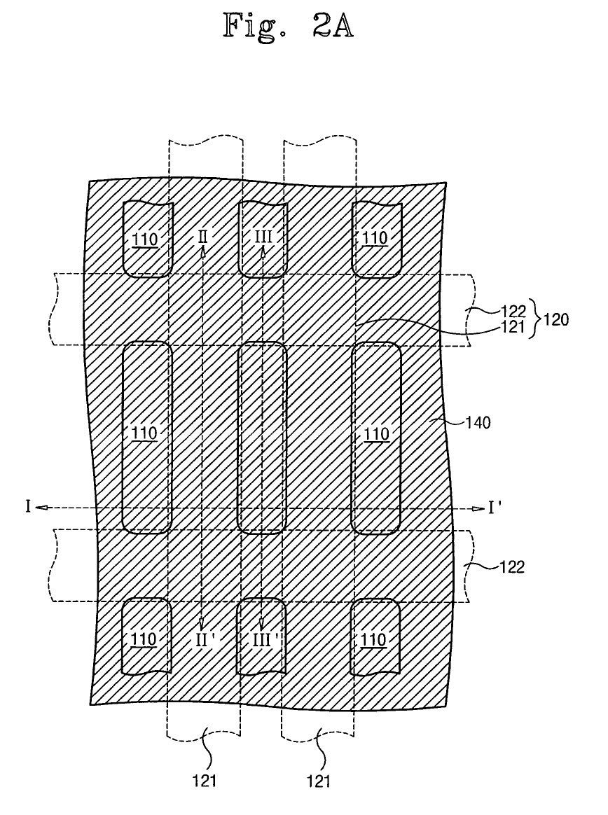

### DETAILED DESCRIPTION OF THE INVENTION

Reference will now be made in detail to the preferred embodiments of the present invention, examples of which are illustrated in the accompanying drawings. It will be understood that when a layer is referred to as being “on” another layer or substrate, it can be directly on the other layer or substrate, or intervening layers may also be present. In the drawings, the thicknesses of layers and regions are exaggerated for clarity. It will be understood that although the terms first and second are used herein to describe various regions, layers and/or sections should not be limited by these terms. These terms are only used to distinguish one region, layer or section from another region, layer or section. Thus, for example, a first layer discussed below could be termed a first layer without departing from the teachings of the present invention. Each embodiment described and illustrated herein includes complementary embodiments thereof.

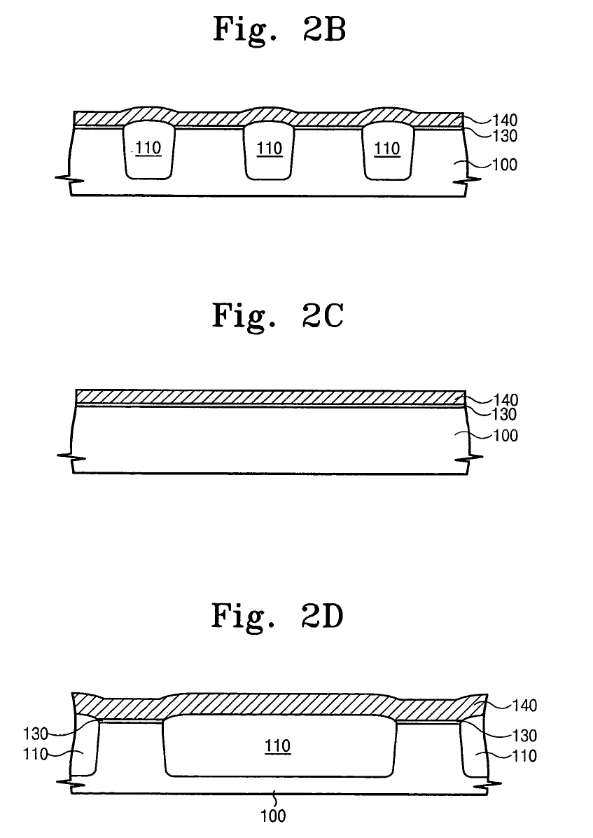

FIGS. 2A through 9A are plan views illustrating a method of fabricating a split-gate-type nonvolatile memory device according to an embodiment of the present invention, FIGS. 2B through 9B are cross sectional views taken along dotted lines I-I′ of FIGS. 2A through 9A, respectively, FIGS. 2C through 9C are cross sectional views taken along dotted lines II-II′ of FIGS. 2A through 9A, respectively, and FIGS. 2D through 9D are cross sectional views taken along dotted lines III-III′ of FIGS. 2A through 9A, respectively.

Referring to FIGS. 2A through 2D, isolation patterns 110 are formed in a predetermined region of a semiconductor substrate 100 to define active regions 120. The isolation patterns 110 may be formed using a shallow trench isolation (STI) technique or a local oxidation of silicon (LOCOS) technique.

The active regions 120 include first active regions 121 and second active regions 122. The first active regions 121 are provided in one direction, while the second active regions 122 are provided in another direction and connect the first active regions 121. During a subsequent process, a channel region and drain region for a transistor are formed in the first active region 121, and a source region for the transistor are formed in the second active region 122.

Thus, the active region 120 forms a mesh-shaped planar structure, and the isolation patterns 110 are 2-dimensionally arranged and enclosed with the active region 120. In this case, each of the isolation patterns 110 takes on a rectangular shape with major and minor axes, and the major axis of each of the isolation patterns 110 is parallel to the first active region 121.

A gate insulating layer 130 is formed on the active region 120 to a thickness of about 50 to 400 Å. The gate insulating layer 130 may be a silicon oxide layer that is obtained through a thermal oxidation process. Alternatively, the gate insulating layer 130 may be an insulating layer including a silicon nitride layer or a silicon oxynitride layer.

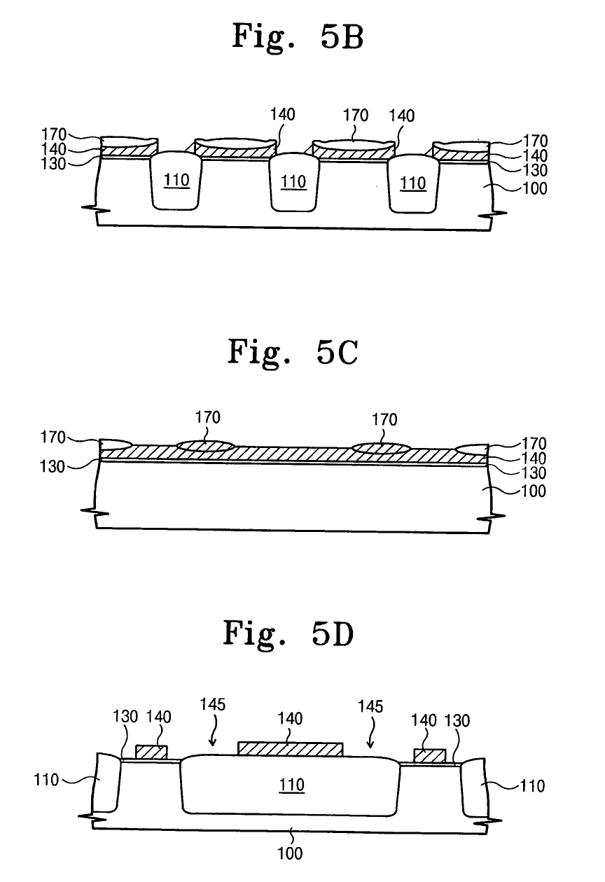

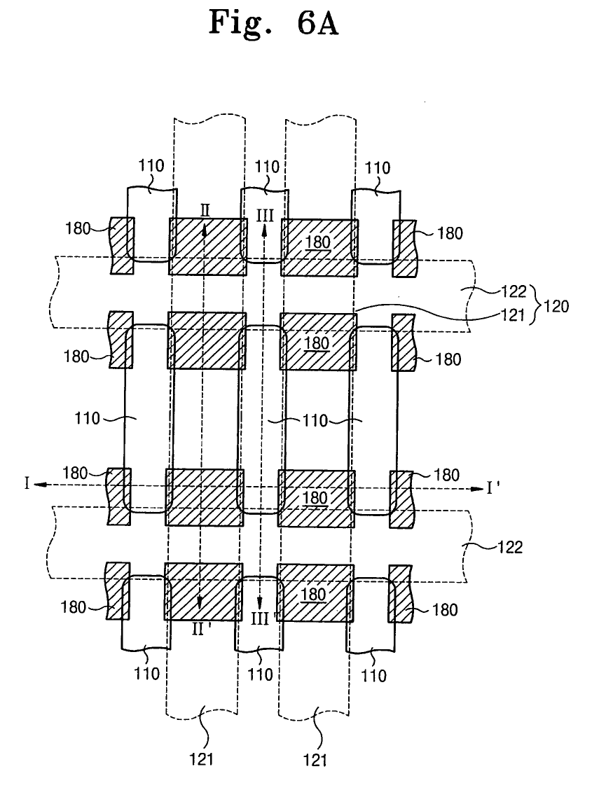

A first conductive layer 140 is formed on the resultant structure having the gate insulating layer 130. The first conductive layer 140 may be formed of poly-Si to a thickness of about 500 to 4000 Å. In this case, the thickness of the first conductive layer 140 is determined considering a thickness that will be reduced in a subsequent process of forming a silicon oxide pattern (refer to 170 of FIG. 5).

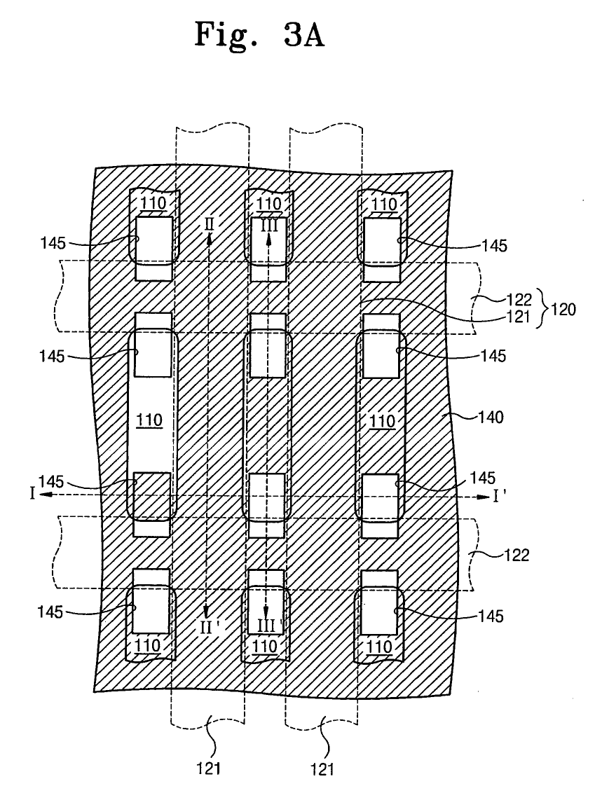

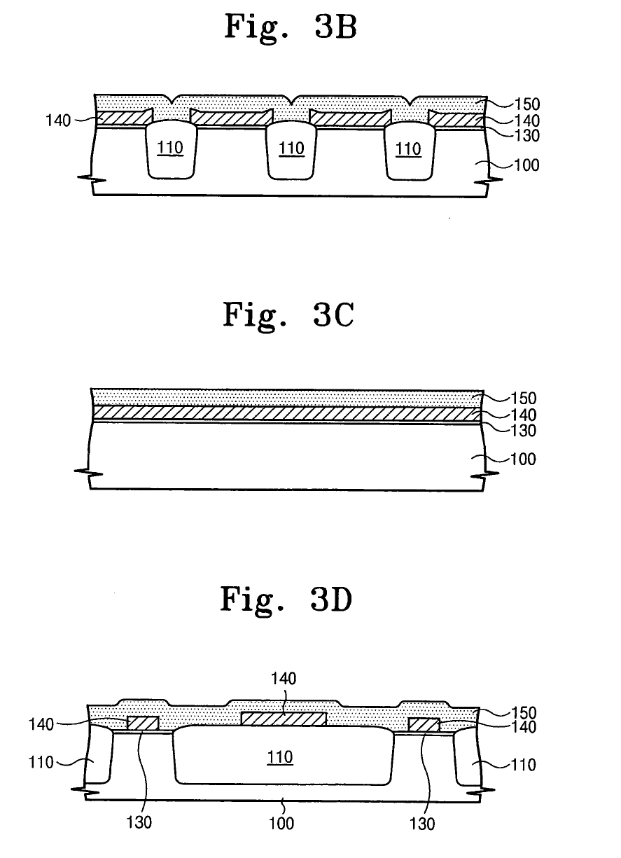

Referring to FIGS. 3A through 3D, the first conductive layer 140 is patterned to have openings 145 exposing top surfaces of the isolation patterns 110. The openings 145 are provided on both ends of the isolation pattern 110 and may partially expose top surfaces of the second active regions 122.

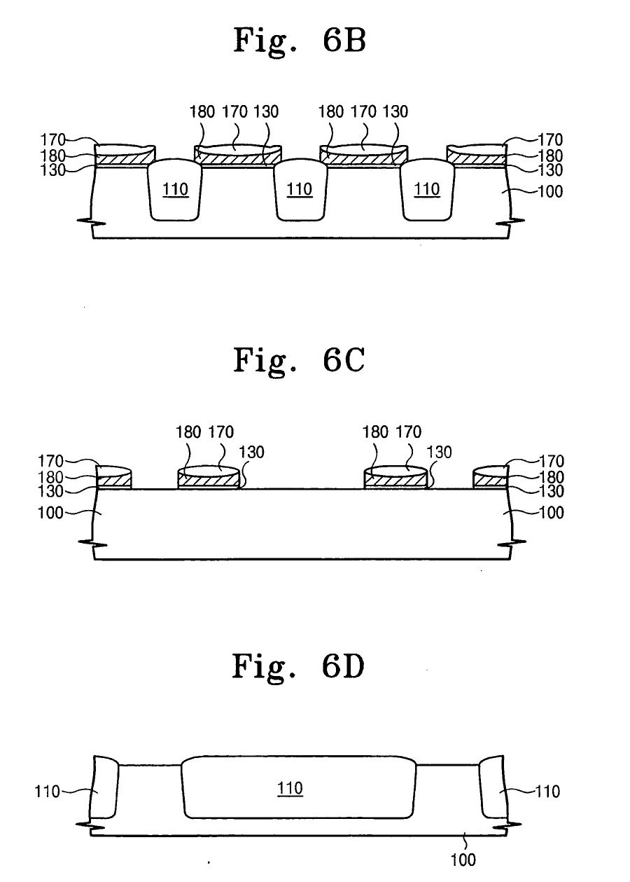

The openings 145 define two sidewalls of a floating conductive pattern (refer to 180 of FIG. 6) that will be formed in a subsequent process. That is, inner walls of the openings 145 are used for defining the sidewalls of the floating conductive pattern 180.

Thereafter, a mask layer 150 is formed on the resultant structure having the openings 145. The mask layer 150 may be formed of a material that can inhibit oxygen atoms injected during a thermal oxidation process from diffusing into the first conductive layer 140. For example, the mask layer 150 may be a silicon nitride layer or a silicon oxynitride layer. Also, the mask layer 150 may be formed to a thickness of about 500 to 3000 Å.

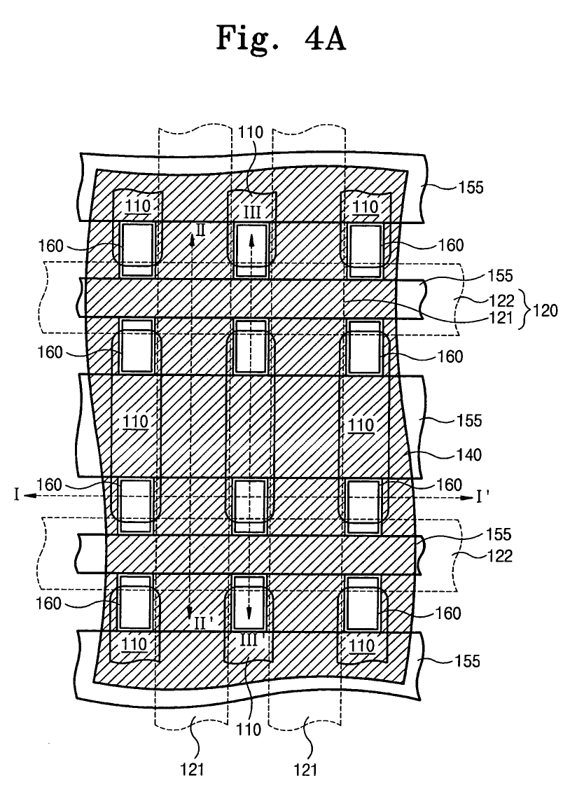

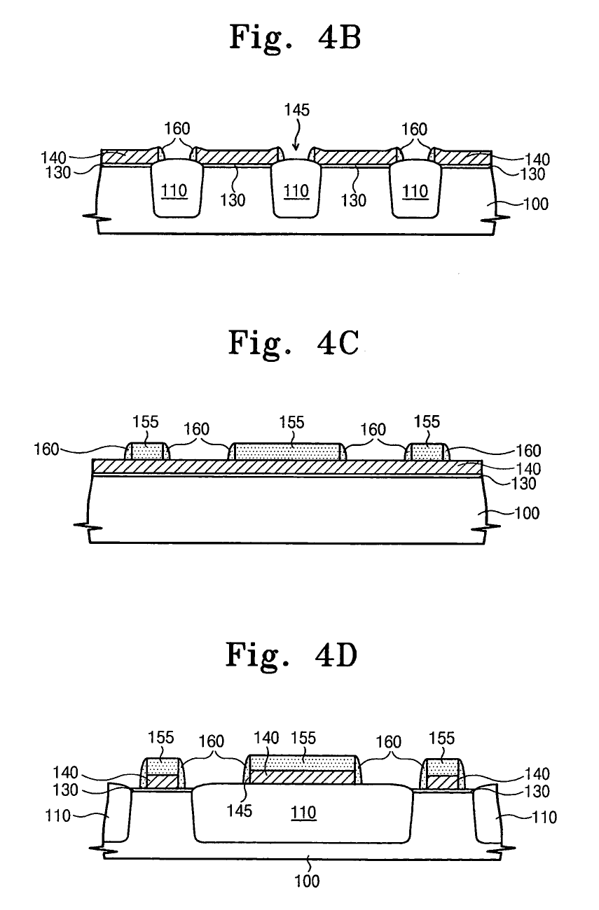

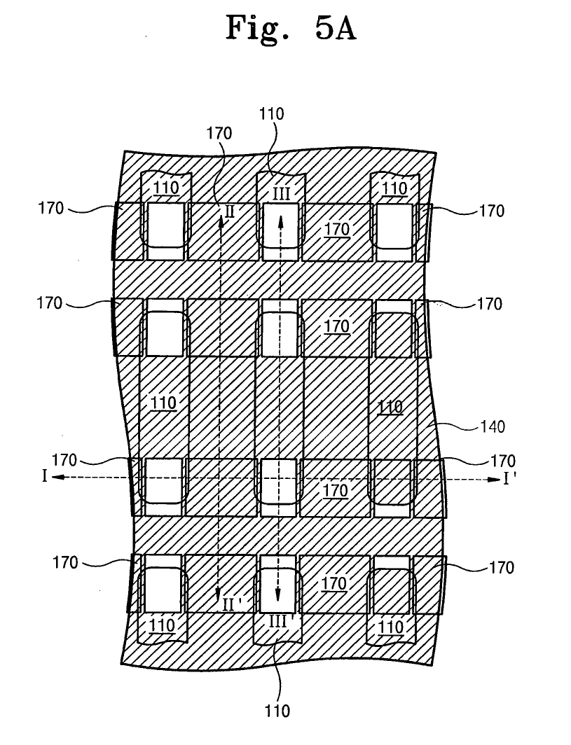

Referring to FIGS. 4A through 4D, the mask layer 150 is patterned to form mask patterns 155 parallel to the second active regions 122. In this case, the mask patterns 155 are provided on the first conductive layer 140 between the openings 145. That is, the mask patterns 155 are formed to expose the openings 145 and a top surface of the first conductive layer 140 interposed between the openings 145. As a result, the top surface of the first conductive layer 140 exposed by the mask patterns 155 forms a rectangle having two sides defined by the openings 145 and other two sides defined by the mask patterns 155.

A spacer layer is formed on the resultant structure having the mask patterns 155 and etched using an anisotropic etching process, thereby forming spacer patterns 160 on sidewalls of the mask patterns 155. As described above, since the mask patterns 155 expose the openings 145, the spacer patterns 160 are formed also on inner walls of the openings 145. As a result, the spacer patterns 160 are formed also on sidewalls of the first conductive layer 140 exposed by the opening 145.

Like the mask patterns 155, the spacer patterns 160 may be formed of a material that can inhibit oxygen atoms injected during a thermal oxidation process from diffusing into the first conductive layer 140. In this case, the spacer patterns 160 may be formed of the same material (e.g., silicon nitride or silicon oxynitride) as the mask patterns 155 in order to facilitate a subsequent removal process. However, the spacer patterns 160 may be formed of a different material from the mask patterns 155.

Referring to FIGS. 5A through 5D, the exposed top surface of the first conductive layer 140 is thermally oxidized using the mask patterns 155 and the spacer patterns 160 as oxidation-resistant masks. Thus, a silicon oxide pattern 170 is selectively formed only on the exposed top surface of the first conductive layer 140.

In the above-described method, the first conductive layer 140 exposed through the thermal oxidation process takes on a rectangular shape enclosed with the mask patterns 155 and the spacer patterns 160. Thus, the silicon oxide pattern 170 may form a rectangle having corners with a very small radius of curvature. In the present embodiment, the corners of the silicon oxide pattern 170 may have a radius of curvature less than half or a tenth the width of the first active region 121.

Afterwards, the mask patterns 155 and the spacer patterns 160 are removed. As a result, an unoxidized top surface of the first conductive layer 140 is exposed around the silicon oxide pattern 170. The removal of the mask patterns 155 and the spacer patterns 160 may be performed by means of a wet etch recipe having an etch selectivity with respect to the silicon oxide pattern 170 and the first conductive layer 140. According to the present invention, a solution containing phosphoric acid may be used as an etchant during the removal process.

Referring to FIGS. 6A through 6D, the exposed first conductive layer 140 is patterned using the silicon oxide patterns 170 as etch masks, thereby forming floating conductive patterns 180 under the silicon oxide patterns 170. The patterning of the exposed conductive layer 140 includes anisotropically etching the first conductive layer 140 by means of an etch recipe having an etch selectivity with respect to a silicon oxide layer. As a result, the isolation patterns 10 and the gate insulating layer 130 may serve as an etch stop layer during the etching process, thus preventing the active regions 120 from being damaged by etching.

Since the silicon oxide pattern 170 has a rectangular shape as stated above, the floating conductive pattern 180 obtained using the silicon oxide pattern 170 as an etch mask may be also formed as a rectangular type having corners with a very small radius of curvature. As a result, there is little difference in the length of the floating conductive pattern 180 irrespective of a distance from the isolation pattern 110 to the floating conductive pattern 180.

More specifically, a difference between the length of the floating conductive pattern 180 on the edge of the first active region 121 and the length of the floating conductive pattern 180 on the center of the first active region 121 may be less than a tenth the smaller one of the two lengths. Because of little difference between the lengths of the floating conductive patterns 180, the corners of the floating conductive patterns 180 may have a radius of curvature less than half or a tenth the width of the first active region 121. As a consequence, the present invention can prevent the floating conductive patterns 180 from having rounded corners due to the photolithographic limit and overcome the deterioration of device characteristics owing to a short channel effect.

In one embodiment of the present invention, the formation of the floating conductive patterns 180 may be performed until top surfaces of the active regions 120 are exposed. For this process, patterning the first conductive layer 140 may be further followed by etching the gate insulating layer 130. The etching of the gate insulating layer 130 may be performed through an anisotropic etching process incorporating an etch recipe having an etch selectivity against silicon by use of the silicon oxide patterns 170 as etch masks.

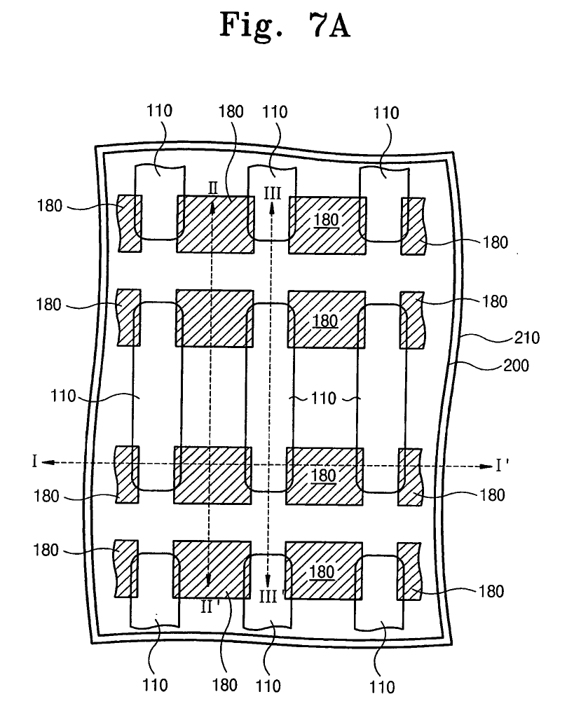

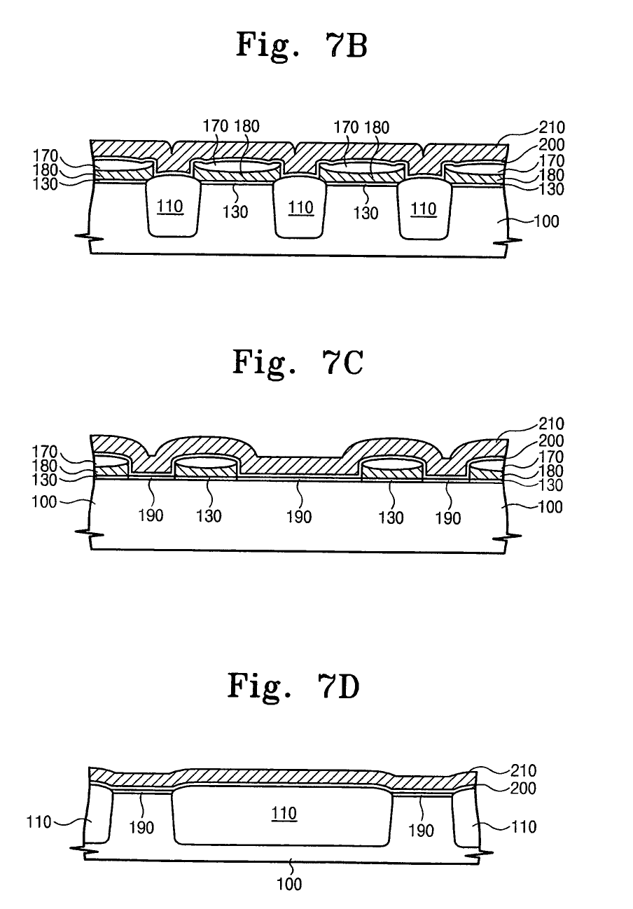

Referring to FIGS. 7A through 7D, an inter-gate dielectric layer 200 and a second conductive layer 210 are sequentially formed on the resultant structure having the floating conductive patterns 180. The inter-gate dielectric layer 200 may be formed of at least one of a silicon oxide layer, a silicon nitride layer, and a silicon oxynitride layer. According to one embodiment of the present invention, the inter-gate dielectric layer 200 may be a medium temperature silicon oxide (MTO) layer obtained through a chemical vapor deposition (CVD) process. The second conductive layer 210 may include at least one of a poly-Si layer, a metal silicide layer, and a metal layer. Preferably, the second conductive layer 210 may include a poly-Si layer and a metal silicide layer that are stacked in sequence.

When the formation of the floating conductive patterns 180 includes etching the gate insulating layer 130 as described above, a tunnel insulating layer 190 may be further formed on the active regions 120 adjacent to the floating conductive patterns 180 before the inter-gate dielectric layer 200 is formed. The tunnel insulating layer 190 may be a silicon oxide layer obtained using a thermal oxidation process.

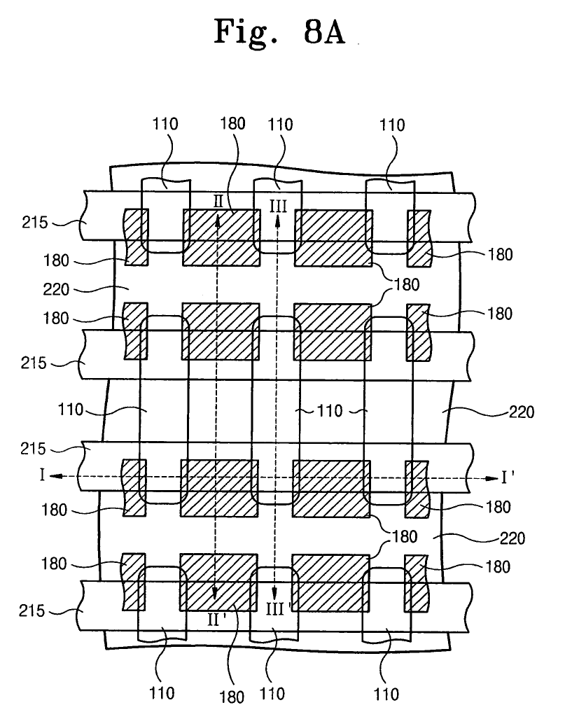

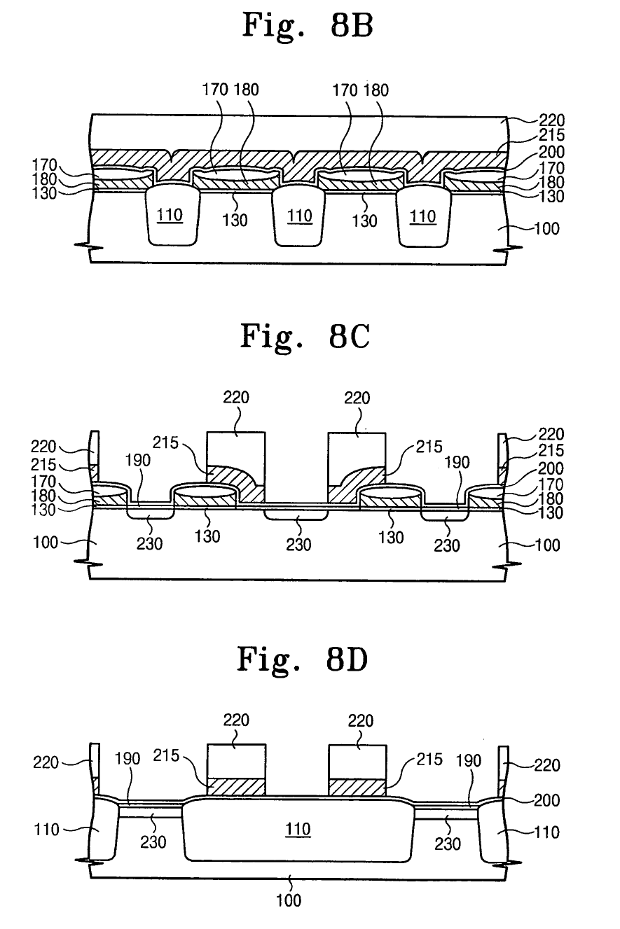

Referring to FIGS. 8A through 8D, photoresist patterns 220 are formed on the second conductive layer 210, and the second conductive layer 210 is patterned using the photoresist patterns 220 as etch masks. Thus, gate lines 215 are formed across the isolation patterns 110. The photoresist patterns 220 and the gate lines 215 are formed across the isolation patterns 110, that is, in a direction parallel to the second active region 122. In this case, the gate lines 215 are used as control gate electrodes of split-gate-type nonvolatile memory transistors. Accordingly, the gate lines 215 are provided not only on the first active regions 121 on one sides of the floating conductive patterns 180 but also on the corners of the floating conductive patterns 180.

Subsequently, an ion implantation process is implemented using the gate lines 215 and the silicon oxide patterns 170 as ion implantation masks, thereby forming impurity regions 230 in the active regions 120. As mentioned above, the impurity regions 230 serve as source and drain electrodes of the split-gate-type nonvolatile memory transistors. The impurity region 230 formed in the first active region 121 is used as a drain electrode, while the impurity region 230 formed in the second active region 122 is used as a source electrode.

Since the silicon oxide pattern 170, which is used as the ion implantation mask during the formation of the impurity regions 230, has the corners with a small radius of curvature as stated above, a reduction in channel length can be prevented unlike in the conventional case.

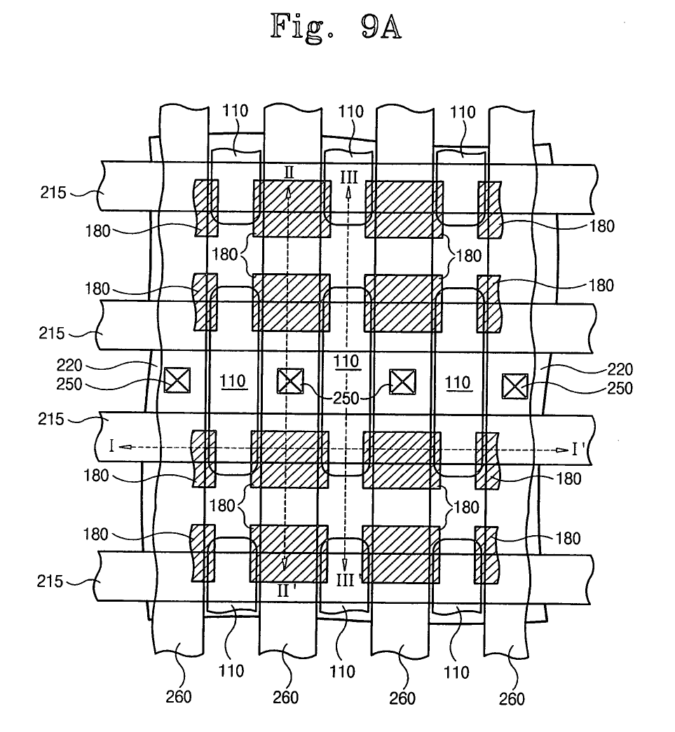

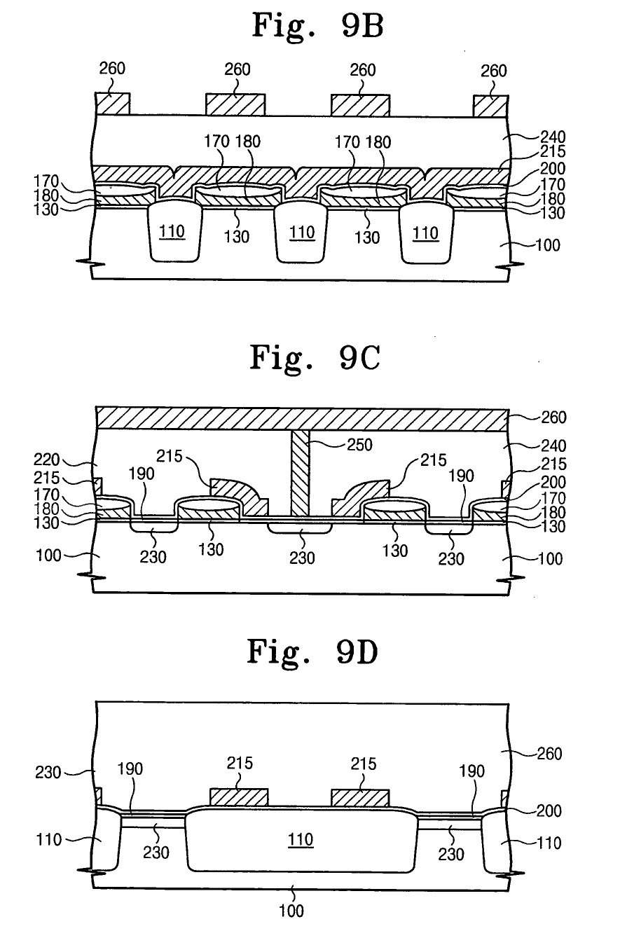

Referring to FIGS. 9A through 9D, the photoresist patterns 220 are removed, and an interlayer dielectric layer (ILD) 240 is formed on the resultant structure having the impurity regions 230. Contact plugs 250 are then formed through the ILD 240 such that the contact plugs 250 are connected to the impurity regions 230. The contact plugs 250 may be connected to the tops of the gate lines 215. Afterwards, interconnection lines 260 are formed to connect the contact plugs 250. In this case, the interconnection lines 260, which are connected to the drain electrodes through the contact plugs 250, serve as bit lines of the split-gate-type nonvolatile memory transistors.

According to the embodiments of the present invention as described above, the first conductive layer is exposed as a rectangular type by performing a first patterning process in a first direction and then performing a second patterning process in a second direction orthogonal to the first direction. Afterwards, the exposed first conductive layer is thermally oxidized to form rectangular silicon oxide patterns with a small radius of curvature. Because the floating conductive patterns according to the present invention are obtained using the silicon oxide patterns as etch masks, the floating conductive patterns also have a small radius of curvature. As a consequence, the present invention can prevent the photoresist patterns from having rounded corners and minimize the occurrence of a short channel effect in spite of an increase in the integration density of semiconductor devices.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of fabricating a split-gate-type nonvolatile memory device, comprising:
forming isolation patterns defining active regions in a predetermined region of a semiconductor substrate;
forming a first conductive layer on the resultant structure having the isolation patterns, the first conductive layer having openings exposing both ends of the isolation patterns;
exposing a top surface of the first conductive layer as a rectangular type by forming mask patterns between the openings on the first conductive layer;
forming silicon oxide patterns with rectangular shapes by thermally oxidizing the exposed top surface of the first conductive layer;
forming floating conductive patterns by anisotropically etching the first conductive layer using the silicon oxide patterns as etch masks; and
forming control gate electrodes across the isolation patterns on the silicon oxide patterns.

2. The method of claim 1, wherein the forming of the first conductive layer having the openings comprises:
forming the first conductive layer on the resultant structure having the isolation patterns; and
forming the openings by patterning the first conductive layer, the openings being 2-dimensionally arranged on the semiconductor substrate and exposing top surfaces of the isolation patterns,
wherein the openings define two sidewalls parallel to major axes of the isolation patterns of the floating conductive patterns.

3. The method of claim 1, further comprising forming spacer patterns on inner walls of the openings before forming the silicon oxide patterns.

4. The method of claim 3, wherein the mask patterns and the spacer patterns are formed of an insulating layer having an etch selectivity with respect to the isolation patterns and the first conductive layer.

5. The method of claim 3, wherein the mask patterns and the spacer patterns are formed of one of a silicon nitride layer and a silicon oxide layer.

6. The method of claim 1, wherein the mask patterns are formed parallel to the control gate electrodes and define two sidewalls vertical to major axes of the isolation patterns of the floating conductive patterns.

7. The method of claim 1, further comprising forming a gate insulating layer on top surfaces of the active regions before forming the first conductive layer.

8. The method of claim 7, wherein the forming of the floating conductive patterns comprises:
anisotropically etching the first conductive layer using the silicon oxide patterns as etch masks until a top surface of the gate insulating layer is exposed; and
anisotropically etching the gate insulating layer using the silicon oxide patterns as etch masks until the top surfaces of the active regions are exposed.

9. The method of claim 8, further comprising forming a tunnel insulating layer on the exposed top surfaces of the active regions after anisotropically etching the gate insulating layer and before forming the control gate electrodes.

10. The method of claim 1, further comprising forming an inter-gate dielectric layer on the resultant structure having the floating conductive patterns before forming the control gate electrodes,
wherein the inter-gate dielectric layer is formed of at least one of a silicon oxide layer and a silicon nitride layer.

11. The method of claim 1, wherein the floating conductive patterns are formed using the rectangular silicon oxide patterns as etch masks so that a difference between the length of the floating conductive pattern measured on the edge of the active region in a vertical direction to the control gate electrodes and the length of the floating conductive pattern measured on the center of the active region in the vertical direction to the control gate electrodes is less than a tenth the smaller one of the two lengths.

12. A split-gate-type nonvolatile memory device comprising:
isolation patterns disposed in a predetermined region of a semiconductor substrate to define active regions;
control gate electrodes disposed across the isolation patterns;
floating conductive patterns interposed between the control gate electrodes and the active regions;
an inter-gate dielectric layer interposed between the control gate electrodes and the floating conductive patterns; and
a gate insulating layer interposed between the floating conductive patterns and the active regions,
wherein the floating conductive patterns have corners with a radius of curvature less than half the width of the active regions.

13. The device of claim 12, wherein the active regions comprise:
first active regions disposed in a vertical direction to the control gate electrodes; and
second active regions connecting the first active regions in a parallel direction to the control gate electrodes,
wherein the isolation patterns have major axes parallel to the first active regions and take on island shapes enclosed with the first and second active regions.

14. The device of claim 13, wherein a pair of control gate electrodes are disposed on each of the isolation patterns across the first active regions.

15. The device of claim 13, wherein the control gate electrodes extend from the tops of the floating conductive patterns to the tops of the first active regions.

16. The device of claim 15, further comprising a tunnel insulating layer interposed between the control gate electrodes and the first active regions.

17. The device of claim 16, wherein the inter-gate dielectric layer is disposed under the control gate electrodes and covers top and lateral surfaces of the floating conductive patterns and the top surface of the tunnel insulating layer.

18. The device of claim 12, wherein the inter-gate dielectric layer is formed of at least one of a silicon oxide layer and a silicon nitride layer.

19. The device of claim 13, wherein a difference between the length of the floating conductive pattern measured on the edge of the first active region and the length of the floating conductive pattern on the center of the first active region is less than a tenth the smaller one of the two lengths.
